(19) United States
(12) Patent Application Publication
(10) Pub. No.: US 2016/0231269 A1
(43) Pub. Date: Aug. 11, 2016

(54) GOLD COATED NATRUAL FIBRE AS ELECTRODE MATERIALS AND PROCESS FOR PREPARATION THEREOF

(71) Applicant: COUNCIL OF SCIENTIFIC AND INDUSTRIAL RESEARCH, Rafi Marg, New Delhi (IN)

(72) Inventors: Pushipito KUMAR GHOSH, Bhavnagar (IN); Divesh NARAYAN SRIVASTAVA, Bhavnagar (IN); Dibyendu MONDAL, Bhavnagar (IN); Mosarrat PERWEEN, Bhavnagar (IN)

(21) Appl. No.: 15/023,027

(22) PCT Filed: Sep. 19, 2014
(86) PCT No.: PCT/IN2014/000613

§ 371 Date: Mar. 18, 2016

(30) Foreign Application Priority Data
Sep. 19, 2013 (IN) 2755/DEL/2013

(51) Int. Cl. G01N 27/30; H01B 1/02; D06M 11/83; C23C 14/20; C23C 14/34

(52) U.S. Cl. CPC G01N 27/307; C23C 14/205; C23C 14/34; D06M 11/83; H01B 1/02; D06M 2101/02

(57) ABSTRACT

The present invention relates to gold wires and electrodes fashioned from natural fibres. In particular, fine natural fibres such as coir fibre, jute fibre, sisal fibre, banana fibre, and human hair, which are mechanically strong and flexible, were used as templates over which an 80-200 nm layer of gold was coated by sputter coating. The composite materials were shown to have low electrical resistivity and functioned normally as electrodes in conventional electrochemical applications such as cyclic voltammetry and anodic stripping voltammetry. Although the present invention focused on the use of single fibres and gold coating exclusively, bundles of naturally aligned fibres and coatings of metals other than gold are logical extensions of the invention.

### FIELD OF THE INVENTION

The present invention relates to gold coated natural fibre as electrode materials comprising natural fibres and gold. Particularly, the present invention relates to utilisation of cost effective, flexible, mechanically strong and wire shaped coir fibre, jute fibre, banana fibre, sisal fibre, and human hair for electrode preparation. More particularly the natural fibre electrode materials were obtained through sputter coating of thin layered gold on the surface of different natural fibres. Still more particularly, the invention relates to use of gold coated natural fibre electrodes as (i) conducting wire, (ii) working electrode materials for the study of cyclic volatammogram of different redox couple in both aqueous and non aqueous media and also in presence of acidic electrolyte, (iii) electrode for amperometric sensing of hydrogen peroxide, and (iv) anodic stripping voltammetry for detection and quantification of toxic heavy metal ions.

### BACKGROUND AND PRIOR ART OF THE INVENTION

The liquid metal, Hg, several metallic solids such as Pt and Au, and other conducting substrates such as graphite are well known electrode materials. Semiconducting materials are also well studied as electrodes in photo-electrochemical processes. Electrochemical processes are conducted on bare electrode surfaces or after various types of modifications such as direct chemical functionalization or through coating of conducting polymers, clays, zeolites, silica, and graphene. Conducting coatings over non conducting substrates are also reported, for example, indium-tin oxide coating on glass that serves as an optically transparent electrode. Although carbon electrodes such as graphite and carbon paste are well known, such carbon is derived either from a mineral resource or petroleum coke. With the growing interest in the value addition of discarded bioresources, tailor-made electrode materials fabricated from biomaterials will rise in demand. Weavable fibers have been converted into electro active textiles used in super capacitors. Twisting configurations of working and counter electrodes in dye-sensitized-solar-cells have also been studied. Reports on the use of bioresources as electrode material are scant.

Reference may be made to the article by Ghosh et al. in JACS, 1983, 105, 5691-5693, wherein fabrication of clay modified electrode is disclosed.

Reference may be made to the article by Yang et al. in Angew. Chem., Int. Ed. 2013, 52, 7545-7548, wherein photovoltaic wire derived from a graphene composite fiber achieving an 8.45% energy conversion efficiency is reported.

Reference may be made to Gui et al. in ACS Nano 2013, 7, 6037-6046, wherein natural cellulose fiber as substrate for super capacitor is disclosed.

Reference may be made to Chen et al. in Chem. Soc. Rev. 2013, 42, 5031-5041, wherein novel solar cells in a wire format is reviewed.

Reference may be made to the article by Kozan et al. in Biosensors & Bioelectronics, 2010, 25, 1143-1148, wherein amperometric detection of benzoyl peroxide in pharmaceutical preparations using carbon paste electrodes with peroxidases naturally immobilized on coconut fibres is disclosed.

Reference may be made to the article by Kozan et al. In Analytica Chimica Acta, 2007, 591, 200-207, wherein biosensing hydrogen peroxide utilizing carbon paste electrodes containing peroxidases naturally immobilized on coconut (Cocus nucifera L.) fibres is disclosed.

Reference may be made to JP 2004277847A dated 7 Oct. 2004 by Hiramatsu et al., wherein metal-coated coconut fibres and their manufacture by electroplating are disclosed.

Reference may be made to KR 2004034631A dated 28 Apr. 2004 by Lee et al., wherein electrode for electric double layer capacitor and method for manufacturing the same is disclosed.

Reference may be made to JP 63091953A dated 22 Apr. 1988 by Fuji et al., wherein electrodes and their preparations are disclosed. Composites of woven or nonwoven cloth of conductive fibres mixed with synthetic or natural or regenerated fibres and a polymer of an aromatic compound is used for electrodes.

Reference may be made to JP 2002237374A dated 23 Aug. 2002 by Iwakoshi et al., wherein Woven, knitted, or nonwoven fabric made of conductive fibres and equipped with electrodes at certain points are claimed.

The conductive fibres are obtained by electro less or electroplating of metals on surfaces of synthetic fibres or their mixtures with natural fibres and the electrodes are formed on the fabric by sewing metal thin wires thereon.

Reference may be made to an article by Bruno et al. in Chemical Communications, 2005, 47, 5896-5898, wherein porous carbon-carbon composite replicated from a natural fibre is disclosed.

Reference may be made to a Patent U.S. 005298048A wherein heat treatable sputter coated glass system is disclosed.

Reference may be made to an article by Bismark et al. in Green Chemistry, 2001, 3, 100-107, wherein Surface characterization of natural fibers; surface properties and the water up-take behavior of modified sisal and coir fibers are disclosed.

Reference may be made to an article by Swift et al. in SCANNING VOL. 22, 310-318 (2000), wherein surface morphology of human hair was investigated by atomic force microscopy (AFM).

Reference may be made to a review article in Advances in Polymer Technology, Vol. 18, No. 4, 351-363 (1999), wherein natural fiber based polymer composites have been documented.

Reference may be made to the ongoing project at “Central Coir Research Institute” Kottayan, India entitled “Design, Development and Analysis of Thin Coated Coir Fiber for Electronic and Other Industrial Applications”, wherein the coir fibers were cut in to small tiny pieces and were heated up to a temperature of 1300-1500° C. for two hours. It was then powdered and pelletized and coated with silver to use in electronic applications. [http://www.ccriindia.org/thin_film.html; as on 10 Sep. 2014].

Reference may be made to an article in Materials Research 2013, 16(4), 903-923, wherein the authors have coated the gold coir fiber for taking SEM images as a protocol of SEM imaging. The coating is too thin and cannot be used in electrode applications.

Reference may be made to an article in Electrochemistry Communications 11 (2009) 764-767, wherein the authors fabricated the gold micro-electrode through chemical liquid deposition method in multiple steps. The conducting surface was achieved after 10-20 cycles of consecutive deposition taking about 2 days.

### OBJECTS OF THE INVENTION

The main object of the present invention is to provide gold coated natural fibre as electrode materials.

Another objective of the present invention is to provide a process for the preparation of sustainable and biodegradable electrode materials thorough simple way from naturally occurring wire shaped fibrous and flexible materials which can be used as alternatives to conventional and synthetic electrode materials.

Yet another objective of the present invention is to use mechanically strong coir fibre, jute fibre, sisal fibre, banana fibre, and human hair as non conducting substrate for electrode fabrication.

Yet another objective of the present invention is to use gold as noble metal for coating purpose on the surface of natural fibres.

Yet another objective of the present invention is to use simple sputter coating technique for gold coating on the surface of the natural fibres.

Yet another objective of the present invention is to fine tune the coating time to raise conductivity of the naturals fibres electrode and to value add the fibre for different electro chemical processes.

Yet another objective of the present invention is to check the suitability of the natural fiber electrode materials as working electrode for the study of cyclic voltammetry in both aqueous and non-aqueous media.

Yet another objective of the present invention is to verify the suitability of the natural fiber electrode materials for further surface modification through electro polymerisation process taking aniline as an example.

Yet another objective of the present invention is to prove the suitability of the natural fibers electrodes toward detection and quantification of toxic heavy metal ions present in aqueous solution through anodic stripping voltammetry.

Yet another objective of the present invention is to check the suitability of these fibers electrodes for amperometric sensing using hydrogen peroxide as an example.

### SUMMARY OF THE INVENTION

Accordingly, present invention provides gold coated natural fibre electrode materials comprising 5-7% (w/w) of gold and 95-97% (w/w) of natural fibre wherein the natural fibres comprise coir fibre, jute fibre, banana fibre, sisal fibre and human hair.

In an embodiment of the present invention, the thickness of the natural fibre is in the range of 2-200 μm.

In another embodiment of the present invention, the thickness of the gold on the fibre is in the range of 80-200 nm.

In yet another embodiment of the present invention, the electrical resistivity of the natural fibre electrodes is in the range of 2×10⁻⁵-4×10⁻⁴ ohm cm at 20-30° C.

In yet another embodiment of the present invention, the Young's Modulus of gold coated natural fibre electrodes is in the range of 2-30 GPa and % strain at break point in the range of 1-40.

In yet another embodiment of the present invention, thermal stability of the gold coated natural fibre electrodes is in the range of 190-250° C.

In yet another embodiment of the present invention, said electrode materials are useful as working electrode in electrochemical applications including cyclic voltammetry in aqueous and non-aqueous media, anodic stripping voltammetry for detection of lead [Pb(II)], arsenic [As(III)] and mercury [Hg(II)] with detection limit of 69 ppb, 12 ppb and 40 ppb, respectively, and amperometric detection of H₂O₂.

In yet another embodiment of the present invention, said fibre can be further coated with conducting polymer or subjected to other forms of modification to expand their utility.

In yet another embodiment of the present invention, it can be employed in microelectronics by virtue of their electrical conductivity, flexibility, mechanical stability and micron level thickness.

In yet another embodiment of the present invention, it can also be readily obtained as aligned fibres such as in the form of a naturally aligned bundle of jute fibre or human hair.

In yet another embodiment of the present invention, the gold coated fibre can be calcined to recover and recycle the gold.

In yet another embodiment, present invention provides a process for the preparation of electrically conducting natural fibres comprising the steps of:
i. picking individual fibres from sources such as mature coconut, banana stem, jute bark, sisal leaves and head full of hair;
ii. washing and drying the fibres if required;
iii. alternatively, collecting a bundle of naturally aligned fibres which are fastened at one end through use of a rubber band or clip or glue to retain the alignment;
iv. placing the fibres in a conventional sputter coater and carrying out gold coating at 7-8 Pa pressure, 3-4 mA applied plasma current and 20-30° C. temperature over 30-90 minutes to obtain fibres having thickness in the range of 50-200 nm;
v. preparing ohmic contact for their functioning as working electrode.

### BRIEF DESCRIPTION OF THE DRAWINGS

FIG. 1 represents EDX of gold coated coir fibre electrode as obtained in example 1.

FIG. 2 represents cyclic voltammogram of 0.5 M sulphuric acid on Au coated human hair electrode (red), and bare gold electrode (black) at scan rate=50 mV/s.

FIG. 3 represents Chronoamperometric response recorded at −0.6 V vs. Ag/AgCl potential for successive addition of 100 μL of 0.05 M H₂O₂ to an initial concentration of 100 μM H₂O₂. [Inset: calibration curve of limiting current vs. concentration of H₂O₂]. The details are given in example 5.

FIG. 4 represents anodic stripping voltammogram (ASV) traces for As (III) along with the calibration plot at different concentration of Pb (II) as described in example 6.

### DETAILED DESCRIPTION OF THE INVENTION

The invention relates to a cost effective and disposable electrode materials fabricated from natural fibres namely, coir fibres, jute fibres, banana fibres, sisal fibres and human hair through sputter coating of gold. The invention recognised that the natural fibres derived from different bio-resources comprise several useful properties e.g. wire like appearance, flexibility, high mechanical strength, and rough surface. In targeting a suitable method, the invention recognised ease of sputter coating technique and was adopted accordingly. Gold was chosen as coating metal recognizing its noble nature and simplicity towards sputter coating. By suitably tuning the gold sputter coating time natural fibres based composites electrode was fabricated which exhibit lower electrical resistivity. By utilizing the composites fibre electrodes in turn, commonly used electrochemical process such as cyclic voltammetry and electrochemical polymerization was tested. The composites fibre electrodes were evaluated in both aqueous and non aqueous solvent. Amperometric sensing of H₂O₂ and toxic metal ions detection by anodic stripping voltammetry using composites fibre as working electrodes was also demonstrated.

Accordingly, a cost effective and flexible natural fibre based composite electrode materials is disclosed. The preparation of gold coated natural fibre electrodes comprising:
(i) Physically picking individual coir fibre strands from mature coconut; banana fibres from chemically treated banana stem as taught in the prior art; jute fibres from physically treated jute bark; sisal fibres from sisal leaves; and human hair from head full of hair;
(ii) washing and drying the fibres before used whenever required;
(iii) Alternatively, collecting a bundle of naturally aligned jute fibres or human hair which are clipped or glued to retain the alignment;
(iv) Placing a bundle of natural fibres in a conventional sputter coater and carrying out gold coating.
(v) Removing the gold coated natural fibres from sputter coater chamber and ensuring ohmic contact for their functioning as electrode materials.
(vi) Finally, testing of the composite fibre electrodes for well known electrochemical experiments such cyclic voltammetry, electro-polymerisation of aniline.
(vii) Testing the suitability of the natural fibre electrodes towards amperometric detection of H₂O₂ and detection of toxic heavy metal ions by anodic stripping voltammetry.

The term pristine is used for raw material as obtained.

The novel inventive steps related to the present invention are as follows:
1. Recognising that low cost, flexible, high mechanical strength, wire shaped natural fibres are an ideal sustainable resource for fabrication of electrically conducting wires and electrodes.
2. Recognising that some of the natural fibres such as jute fibre are extremely fine and wires made from these may be quite useful in microelectronics.
3. Recognising further that such fibres are, in many cases, naturally aligned, such as a headful of straight hair, and can be utilized for naturally aligned mat electrodes.
4. Recognising that gold can be easily sputter coated on the surface of the natural fibres to create such conducting wires for their functioning as gold electrodes particularly in sensing and detection applications where typically low current densities are encountered.
5. Recognizing that not only is gold easy to coat, gold electrodes have many useful applications as electrodes by virtue of its inert nature.
6. Further recognising that an 80-200 nm gold coating suffices for this purpose, this amounting to 5-7% of the total weight of the composite electrode.
7. Further demonstrating best performance with jute fibre and human hair in so far as electrical resistivity and peak-to-peak separation in cyclic voltammetry are concerned.
8. Further demonstrating the utility of the electrode made from human hair in anodic stripping voltammetry with ppb level detection.

### EXAMPLES

Following examples are given by way of illustration and should not be construed to limit the scope of the invention.

### Materials and Methods

Dry coir fibres of uniform diameter (150-200 μm), having Young's modulus 5-7 GPa and strain 7-11% was physically picked from fully matured coconut fruit (Prerna Stores, Waghawadi Road, Bhavnagar, Gujarat-364002, India) and selected for the study without any chemical pre-treatment. Banana fibre (Prerna Stores, Waghawadi Road, Bhavnagar, Gujarat-364002, India) was extracted by known method of chemical pretreatment. Thus obtained banana fibres had thickness 10-30 μm, Young's modulus 7-10 GPa and strain 2-4%. Jute and sisal fibres (Prerna Stores, Waghawadi Road, Bhavnagar, Gujarat-364002, India) with thickness of 2-10 μm and 40-80 μm respectively, used in the present invention had Young's modulus 25-26 GPa and 20-25 GPa respectively and strain 1-3% and 8-12% respectively. The human hairs used in the present invention had thickness 30-50 μm and Young's modulus 2-3 GPa, strain 35-40%, This example teaches the extraction/source of different natural fibres and their mechanical properties which were used in the present invention. Tensile strength testing was carried out using a universal testing machine (Zwick Roell, type X force P, S/N 756324). Young's modulus (Y) was determined from the regression slope in the elastic region of the stress-strain curve. Au coating of coir fiber was performed using Polaron SC7620 mini-sputter at 8 Pascal pressure. The thickness of Au coating on the surface of the fibre was determined using the following equation.

d=KIVt (1)

where d is the coating thickness in angstrom; K is an experimentally determined constant (for Au used with air, K=0.07 approximately); I is the plasma current in mA (5 mA in present invention), V is the bias voltage in kV (1 kV in present invention), and t is the sputtering time in seconds (3600 s in present invention). Current-voltage (I-V) measurements were performed using a Keithley 2635A source meter unit (SMU). The contacts on the natural fibre electrodes for measurement of I-V characteristics were made using conducting silver paste and copper wire. The copper wire was connected to the source meter unit (SMU) with a crocodile clip. The bias current of ±1.0 mA was applied, and corresponding voltage was measured. The sweep was generated by the instrument, and 32 measured data points were averaged automatically. The averaged and stored data were collected and plotted to obtain the I-V curve. The electrical resistances of the natural fibre electrodes were calculated from the slope of the curve. The specific resistance of the coating was calculated considering it as a sheet and applying the equations: Specific resistance ρ=R×(W×L)/H; wherein W is the width of the sheet (thickness of the coating), L is length of the sheet (circumference of the coating, i.e., 2πr), H is height (length of the fiber between two contacts); and R is measured resistance (from slope of I-V curve). Electrochemical experiments were performed using a Princeton applied research potentiostat (PAR-STAT 2273) at room temperature (24±2° C.). A three-electrode assembly was used in all measurements in which Au-coated coir fiber or Au wire (in control experiment) was used as working electrodes, while platinum foil and Ag/AgCl (sat KCl) were used as auxiliary and reference electrodes, respectively. The contact in the working electrode was made through a spring-loaded clip, which was suitably modified.

### Example 1

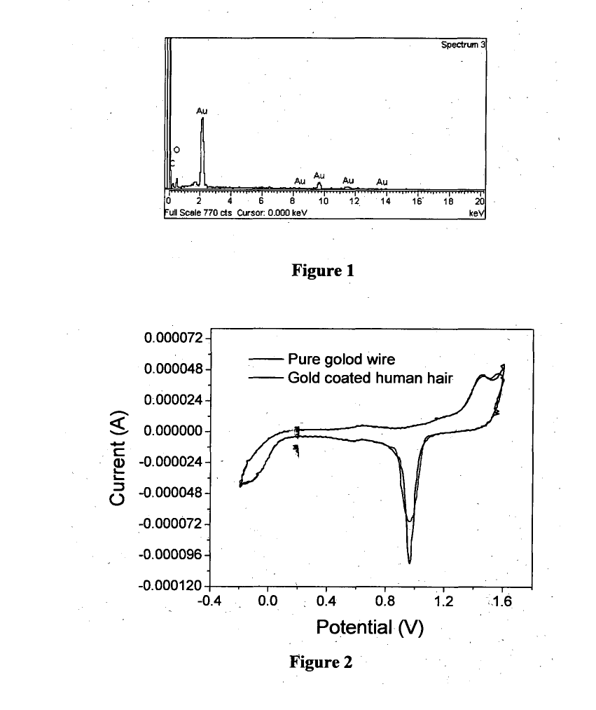

For coatings of Au, a bundle of coir fibers (75 to 100) as described in materials and method section were placed into the chamber of a sputter coater (100 mm diameter×100 mm height). The vapor pressure of gold was maintained uniformly in the chamber which facilitated uniform coating. After 60 min of coating, the fibers were removed from the coater and characterized. The data on physical properties of different fibres are provided in Table 1 and EDX of gold coated coir fibre is given as FIG. 1.

This example teaches that Young's modulus and strain at breaking point of the natural fibres were in the range of 2-30 GPa and 1-40%. The example further teaches that maximum strain at breaking point was 35-40% in case of human hair. This example also teaches amount of gold coated on natural fibres was 5-7% (w/w) and specific resistivity was in the range of 4e⁻⁴ to 2e⁻⁵ Ω cm. Further this example teaches that lowest resistivity was obtained with 2B and 4B respectively. Thickness of gold coating for all samples were in the range of 80-200 nm.

TABLE 1
Different physical properties of uncoated and gold coated natural fibre
electrode.

| | | | | Young's | Strain at | |
|---|---|---|---|---|---|---|
| | Thickness | Moisture | Gold | modulus | breaking | Resistivity (Ω cm) |
| Sample | (μm) | (%) | (% w/w) | (GPa) | (%) | at 25° C. |
| 1A | 100-200 | 13.9 | — | 6.5 | 9.5 | ND |
| 1B | ″ | 11.8 | 5.6 | 8.3 | 14.0 | 4.4 × 10⁻⁴ |
| 2A | 30-50 | 14.2 | — | 2.6 | 38.05 | ND |
| 2B | ″ | 13.9 | 5.8 | 3.2 | 39.02 | 3.18 × 10⁻⁵ |
| 3A | 40-70 | 12.5 | — | 25.8 | 9.03 | ND |
| 3B | ″ | 8.5 | 5.3 | 28.1 | 9.85 | 7.38 × 10⁻⁵ |
| 4A | 2-10 | 10.4 | — | 26.4 | 1.74 | ND |
| 4B | ″ | 11.1 | 6.5 | 27.6 | 2.00 | 2.87 × 10⁻⁵ |
| 5A | 10-30 | 9.7 | — | 7.6 | 2.78 | ND |
| 5B | ″ | 8.2 | 5.1 | 8.3 | 3.05 | 8.83 × 10⁻⁵ |

ND = Not determined;
1A = uncoated coir fibre;
1B = Au coated coir fibre;
2A = uncoated human hair;
2B = Au coated human hair;
3A = uncoated sisal fibre;
3B = Au coated sisal fibre;
4A = uncoated jute fibre;
4B = Au coated jute fibre;
5A = uncoated banana fibre; and
5B = Au coated banana fibre.

### Example 2

Cyclic voltammogram of 0.5 M sulphuric acid was recorded in a 10 mL open cell where gold coated human hair and bare gold act as working electrode while platinum foil and Ag/AgCl (sat KCl) were employed as counter and reference electrode respectively. Scan rate 50 mV/s and potential range −0.2V to 1.6 V was chosen for this experiment. The cyclic voltammogram is provided in FIG. 2.

This example teaches the stability and cleanness of gold coated natural fibers in acid media and the similarities of CVs with that of pure gold. The gold coated human hair had clean surface and stable in acidic media.

### Example 3

Cyclic voltammetry (CV) of ferrocyanide/ferricyanide redox couple were recorded at 100 mV/s scan rate in a solution having 10 mM potassium ferrocyanide in 0.1 M KCl using gold coated coir fibre, sisal fibre, jute fibre, banana fibre and human hair as working electrode. Comparison was also made with a conventional gold wire electrode. The data on peak to peak separation are provided in Table 2.

Cyclic voltammetry study in acetonitrile medium was carried out using Au coated natural fibres as working electrode CVs were recorded under N₂ atmosphere in an airtight cell. One mM solution of [Ru(bpy)₃]Cl₂ was prepared in dry acetonitrile in the presence of 0.1 M tetraethylammonium tetrafluoroborate (supporting electrolyte). N₂ was purged for 10 min before start of the experiment. CVs were recorded at 350 mV/s scan rate without any agitation. The data on peak to peak separation is given in Table 2.

TABLE 2
Peak to peak separation in aqueous and non aqueous
media for different natural fibre electrodes.

| Natural | 10 mM Fe(CN)₆^{3-/4-} in | 1.0 mM Ru(bpy)₃^{3+/2+} in 0.1 M |
|---|---|---|
| fibre | 0.1 M KCl; 100 mV/s | tetraethylammonium tetrafluoroborate/ |
| electrode | scan rate (mV) | CH₃CN; 350 mV/s scan rate (mV) |
| 1 B | 265 | 305 |
| 2 B | 150 | 124 |
| 3 B | 172 | 160 |
| 4 B | 151 | 107 |
| 5 B | 170 | 172 |
| Gold wire | 85 | — |

1 B = Au coated coir fibre;
2 B = Au coated human hair;
3 B = Au coated sisal fibre;
4 B = Au coated jute fibre; and
5 B = Au coated banana fibre.

This example teaches that the peak to peak separation in aqueous and nonaqueous media mirrored the trends of specific resistivity as mention in Table 1, the separations being the least for jute fibre and human hair. For comparison, the peak-to-peak separation recorded on conventional gold wire electrode is also shown in the table.

### Example 4

An attempt was made to electrochemically coat polyaniline over the surface of the natural fibre electrodes. Anilinium sulfate monomer was prepared by dissolving 0.1M aniline in 0.5 M H₂SO₄ followed by sonication for 6 min. Electro-polymerization was carried out in an open glass cell using 10 mL of freshly prepared monomer. A total of 5-35 potentiodynamic cycles were run in potential window of −0.2 to 0.8 V vs Ag/AgCl. All the natural fibre electrodes could be coated in this manner.

This example teaches that the surface of the natural fibre electrode can be further modified through electro polymerisation.

### Example 5

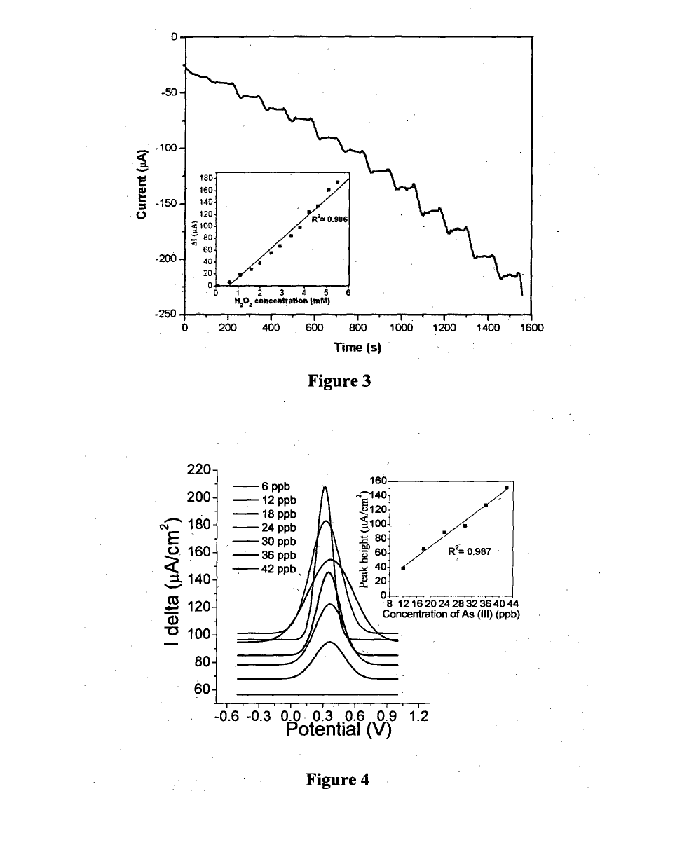

Hydrogen peroxide was detected using Au coated coir fibre electrode. Amperometric measurements were done in open glass cell containing 10 mL H₂O₂ (100 μM) in 0.1 M phosphate buffer (pH 5.2) under continuous stirring. The indicator electrode (coir electrode) was potentiostated at −0.6 V vs. Ag/AgCl. An aliquot of 100 μL of 0.05 M H₂O₂[prepared in 0.1 M phosphate buffer (pH 5.2)] was added successively and the limiting current was measured after 2 minutes, although the response was instantaneous. The data on H₂O₂ sensing is given FIG. 3.

This example teaches amperometric detection of hydrogen peroxide can done using coir fibre electrode. The responses were found instantaneous indicating efficient electron transfer through the coir electrode. The detection limit was found to be 6×10⁻⁴ M.

### Example 6

Anodic stripping voltammetric (ASV) detection of heavy metal ions [Pb (II), Hg (II), and As (III)] was attempted on Au coated human hair used as working electrode. Pt foil and Ag/AgCl (saturated KCl) were used as counter and reference electrodes, respectively. 0.1 M acetate buffer of pH 4.0 was used as electrolyte. For ASV of Pb (II), a stock solution of 25 ppm (concentration of stock solution was cross checked by ICP analysis) was prepared from 1000 ppm solution of PbCl₂. Initially, a blank experiment (without any analyte) was run to check the background current. Thereafter certain volume (10-40 μL) of Pb (II) stock solution was added successively in a cell containing 10 mL acetate buffer. Electrode position was carried out by applying −0.8 V for 10 minutes under stirring condition. Subsequently, a square wave voltammetry waveform was applied in the range of −0.3 to 0.3V to obtain a stripping voltammogram maintaining 25 mV pulse width for 10 millisecond and step height 2 mV. The electrode was washed after each experiment by applying 0.8V potential in blank electrolyte for 10 minutes. To insure complete washing the process was repeated several time and checked for any oxidation peak if there. Peak current values were corrected from background current associated with blank scan. The corrected values of peak current and concentration were used to draw calibration plot. For ASV of Hg (II), 25 ppm stock solution of Hg (II) was prepared from 1000 ppm solution of HgCl₂. The scanning potential range was −0.6 to 0.7V. The other experimental conditions were same as mentioned above. For ASV of As (III), 25 ppm stock solution of As (III) was prepared from 1000 ppm solution of As₂O₃. The scanning potential range was −0.5 to 1.0V. The other experimental conditions were same as mentioned above. FIG. 4 shows the ASV traces for As(III) along with the calibration plot. Table 3 provides data on the detection limits of Pb(II), Hg(II) and As(III).

TABLE 3
Data on lower detection limit of Pb (II),
Hg (II), and As(III) as obtained by anodic
stripping voltammetry on gold coated
human hair as working electrode.
Detection Limit/ppb

| Pb(II) | Hg (II) | As (III) |
|---|---|---|
| 69 | 16 | 12 |

This example teaches use of human hair electrode for ppb level detection and quantification of toxic heavy metals and As(III) in water by ASV.

### ADVANTAGES OF THE INVENTION

The advantages of the present invention are—
(i) Use of inexpensive natural fibres bestowed with excellent properties such as high strength, flexibility and natural alignment of bundles of fibres in several cases as sustainable resources for fabrication of electrically conducting wires and electrodes.
(ii) Ease of preparation of such electrically conducting natural wires and electrodes through sputter coating of gold.
(iii) A true composite electrode wherein useful properties such as flexibility, mechanical strength, fineness are drawn from the inexpensive natural fibres whereas electrical conductivity is drawn from precious gold, and as a result minimizing the requirement of gold to only 5-7% of total weight as compared to a conventional gold electrode.
(iv) Recognising that although gold coated natural fibre electrodes would have lower current carrying capacity than bulk gold wire, such electrodes adequately serve the purpose in electrochemical sensing applications where low current density is required.
(v) Gold can be recycled and reused after burning the natural fibre.

We claim:

1. Gold coated natural fibre electrode materials comprising 5-7% (w/w) of gold and 95-97% (w/w) of natural fibre wherein the natural fibres comprise coir fibre, jute fibre, banana fibre, sisal fibre and human hair.

2. The gold coated natural fibre as claimed in claim 1, wherein the thickness of the natural fibre is in the range of 2-200 μm.

3. The gold coated natural fibre as claimed in claim 1, wherein the thickness of the gold on the fibre is in the range of 80-200 nm.

4. The gold coated natural fibre as claimed in claim 1, wherein the electrical resistivity of the natural fibre electrodes is in the range of 2×10⁻⁵-4×10⁻⁴ ohm cm at 20-30° C.

5. The gold coated natural fibre as claimed in claim 1, wherein the Young's Modulus of gold coated natural fibre electrodes is in the range of 2-30 GPa and % strain at break point in the range of 1-40.

6. The gold coated natural fibre as claimed in claim 1, wherein thermal stability of the gold coated natural fibre electrodes is in the range of 190-250° C.

7. The gold coated natural fibre as claimed in claim 1, wherein said electrode materials are useful as working electrode in electrochemical applications including cyclic voltammetry in aqueous and non-aqueous media, anodic stripping voltammetry for detection of lead [Pb(II)], arsenic [As(III)] and mercury [Hg(II)] with detection limit of 69 ppb, 12 ppb and 40 ppb, respectively, and amperometric detection of H₂O₂.

8. The gold coated natural fibre as claimed in claim 1, wherein said fibre can be further coated with conducting polymer or subjected to other forms of modification to expand their utility.

9. Electrically conducting natural fibres as claimed in claims 1-8, wherein it can be employed in microelectronics by virtue of their electrical conductivity, flexibility, mechanical stability and micron level thickness.

10. Electrically conducting natural fibres as claimed in claims 1-9, wherein it can also be readily obtained as aligned fibres such as in the form of a naturally aligned bundle of jute fibre or human hair.

11. Electrically conducting natural fibres as claimed in claims 1-10, wherein the gold coated fibre can be calcined to recover and recycle the gold.

12. A process for the preparation of electrically conducting natural fibres comprising the steps of:
i. picking individual fibres from sources such as mature coconut, banana stem, jute bark, sisal leaves and head full of hair;
ii. washing and drying the fibres if required;
iii. alternatively, collecting a bundle of naturally aligned fibres which are fastened at one end through use of a rubber band or clip or glue to retain the alignment;
iv. placing the fibres in a conventional sputter coater and carrying out gold coating at 7-8 Pa pressure, 3-4 mA applied plasma current and 20-30° C. temperature over 30-90 minutes to obtain fibres having thickness in the range of 50-200 nm;
v. preparing ohmic contact for their functioning as working electrode.
